(19) United States
(12) Patent Application Publication
(10) Pub. No.: US 2023/0180628 A1
(43) Pub. Date: Jun. 8, 2023

(54) MAGNETORESISTIVE EFFECT ELEMENT, SEMICONDUCTOR DEVICE, AND ELECTRONIC EQUIPMENT

(71) Applicant: SONY SEMICONDUCTOR SOLUTIONS CORPORATION, KANAGAWA (JP)

(72) Inventors: EIJI KARIYADA, TOKYO (JP); YO SATO, KANAGAWA (JP)

(21) Appl. No.: 17/999,746

(22) PCT Filed: Apr. 20, 2021
(86) PCT No.: PCT/JP2021/015942

§ 371 Date: Nov. 23, 2022

(30) Foreign Application Priority Data
Jun. 10, 2020 (JP) 2020-100685

(51) Int. Cl. H10N 50/85; H10N 50/10; H10B 61/00

(52) U.S. Cl. CPC H10N 50/85; H10N 50/10; H10B 61/20

(57) ABSTRACT

Provided is a magnetoresistive effect element having a relatively high magnetoresistance ratio (MR ratio) while reducing element resistance (RA). The magnetoresistive element includes: a first oxide insulating layer provided on one surface side of a magnetization fixed layer; a magnetization free layer provided on the opposite side of the first oxide insulating layer from the magnetization fixed layer side and having perpendicular magnetic anisotropy; a second oxide insulating layer provided on the opposite side of the magnetization free layer from the first oxide insulating layer side; and a metal cap layer provided on the opposite side of the second oxide insulating layer from the magnetization free layer side. The thickness of the second oxide insulating layer is larger than the thickness of the first oxide insulating layer.

### TECHNICAL FIELD

The present technology (a technology according to the present disclosure) relates to a magnetoresistive effect element, a semiconductor device, and electronic equipment.

### BACKGROUND ART

As a semiconductor device, a nonvolatile semiconductor device called a magnetic random-access memory (MRAM) is known. In this MRAM, a magnetoresistive effect element having a magnetic tunnel junction (MTJ) in which two magnetic layers are laminated with a thin insulating film provided therebetween is used as a storage element of a memory cell.

For the magnetoresistive effect element, various structures have been proposed. For example, Patent Document 1 discloses a magnetoresistive effect element with a laminated structure in which a first nonmagnetic layer is provided between a first ferromagnetic layer having a fixed magnetization direction and a second ferromagnetic layer having a variable magnetization direction, and a second nonmagnetic layer is further provided on the opposite side of the second ferromagnetic layer from the first nonmagnetic layer. Then, it is also disclosed that the first ferromagnetic layer acts as a fixed layer, the second ferromagnetic layer acts as a recording layer, and the first nonmagnetic layer is an insulator containing oxygen. Moreover, it is also disclosed that at least one of the first ferromagnetic layer or the second ferromagnetic layer includes a ferromagnetic material containing at least one 3d transition metal, and its film thickness is adjusted to 3 nm or less, whereby the magnetization direction is controlled to be perpendicular to the film surface by magnetic anisotropy at the interface with the first nonmagnetic layer. Furthermore, it is also disclosed that the second nonmagnetic layer acts as a control layer that controls the magnetization direction of the second ferromagnetic layer.

### CITATION LIST

### Patent Document

Patent Document 1: Japanese Patent Application Laid-Open No. 2014-207469

### SUMMARY OF THE INVENTION

### Problems to be Solved by the Invention

Meanwhile, a structure like that of the magnetoresistive effect element disclosed in Patent Document 1 is generally used, and a magnesium oxide (MgO) film is generally used as each of the first and second nonmagnetic layers. In this structure, the MgO film, which is each of the first nonmagnetic layer and the second magnetic layer, is usually set to a thickness of about 0.9 nm to 1.1 nm. In a case where element resistance (RA) is designed to be about 8 to 10 (Ω·um²), the thickness of the MgO film in the first nonmagnetic layer is limited to about 0.9 nm to 1 nm. The thickness of the MgO film in the second nonmagnetic layer has generally been formed in the same film thickness range from the viewpoint of film formation time.

It has been found that the magnetic characteristics of the second ferromagnetic layer deteriorate when the magnetoresistive effect element including the first and second nonmagnetic layers each including the MgO film having the thickness as thus described undergoes a process at a relatively high temperature for a relatively long time. Then, it has been found essential to use a thicker MgO film as the second nonmagnetic layer in order to reduce such deterioration in magnetic characteristics and enhance the perpendicular magnetic anisotropy of the ferromagnetic layer.

However, it has become clear that increasing the thickness of the second nonmagnetic layer (MgO film) causes a problem that the resistance-area product (the product of a resistance R and an area A of the element (RA)) increases, and a magnetoresistance ratio (MA ratio) decreases.

An object of the present technology is to provide a magnetoresistive effect element that reduces element resistance (RA) and has a relatively high magnetoresistance ratio (MR ratio), and a semiconductor device and electronic equipment including the magnetoresistive effect element.

### Solutions to Problems

A magnetoresistive effect element according to an aspect of the present technology includes:

a magnetization fixed layer;

a first oxide insulating layer provided on one surface side of the magnetization fixed layer;

a magnetization free layer provided on an opposite side of the first oxide insulating layer from the magnetization fixed layer side and having perpendicular magnetic anisotropy;

a second oxide insulating layer provided on an opposite side of the magnetization free layer from the first oxide insulating layer side; and

a metal cap layer provided on an opposite side of the second oxide insulating layer from the magnetization free layer side.

The thickness of the second oxide insulating layer is larger than the thickness of the first oxide insulating layer.

A semiconductor device according to another aspect of the present technology includes

a memory cell in which a magnetoresistive effect element and a selecting transistor are connected in series.

The magnetoresistive effect element includes

a magnetization fixed layer,

a first oxide insulating layer provided on one surface side of the magnetization fixed layer,

a magnetization free layer provided on an opposite side of the first oxide insulating layer from the magnetization fixed layer side and having perpendicular magnetic anisotropy,

a second oxide insulating layer provided on an opposite side of the magnetization free layer from the first oxide insulating layer side, and

a metal cap layer provided on an opposite side of the second oxide insulating layer from the magnetization free layer side.

The thickness of the second oxide insulating layer is larger than the thickness of the first oxide insulating layer.

Electronic equipment according to another aspect of the present technology includes

a semiconductor device including a magnetoresistive effect element.

The magnetoresistive effect element includes

a magnetization fixed layer,

a first oxide insulating layer provided on one surface side of the magnetization fixed layer,

a magnetization free layer provided on an opposite side of the first oxide insulating layer from the magnetization fixed layer side and having perpendicular magnetic anisotropy,

a second oxide insulating layer provided on an opposite side of the magnetization free layer from the first oxide insulating layer side, and

a metal cap layer provided on an opposite side of the second oxide insulating layer from the magnetization free layer side.

The thickness of the second oxide insulating layer is larger than the thickness of the first oxide insulating layer.

### BRIEF DESCRIPTION OF DRAWINGS

FIG. 1A is a schematic cross-sectional view illustrating a configuration example of a magnetoresistive effect element according to a first embodiment of the present technology.

FIG. 1B is a characteristic diagram illustrating the dependency of element resistance (RA) and a magnetoresistance ratio (MR ratio) on the thickness of a second nonmagnetic layer in the multilayer of the magnetoresistive effect element according to the first embodiment of the present technology.

FIG. 2A is a schematic cross-sectional view illustrating a configuration example of a conventional magnetoresistive effect element.

FIG. 2B is a characteristic diagram illustrating the dependency of the element resistance (RA) and the magnetoresistance ratio (MR ratio) on the thickness of a second oxide insulating layer in the conventional magnetoresistive effect element of FIG. 2A.

FIG. 3 is a characteristic diagram illustrating a relationship between a material of a crystallization inhibiting layer and the magnetoresistance ratio (MR ratio).

FIG. 4A is a characteristic diagram illustrating a magnetization curve (M-H loop) of a magnetization free layer, the dependency of the element resistance (RA) and the magnetoresistance ratio (MR ratio) on the thickness of an inserted Mo film, and the dependency of the holding capacity (Hc) of the magnetization free layer on the thickness of the inserted Mo film in a case where the Mo film thickness is 0.1 nm.

FIG. 4B is a characteristic diagram illustrating the magnetization curve (M-H loop) of the magnetization free layer, the dependency of the element resistance (RA) and the magnetoresistance ratio (MR ratio) on the thickness of the inserted Mo film, and the dependency of the holding capacity (Hc) of the magnetization free layer on the thickness of the inserted Mo film in a case where the Mo film thickness is 0.2 nm.

FIG. 4C is a characteristic diagram illustrating the magnetization curve (M-H loop) of the magnetization free layer, the dependency of the element resistance (RA) and the magnetoresistance ratio (MR ratio) on the thickness of the inserted Mo film, and the dependency of the holding capacity (Hc) of the magnetization free layer on the thickness of the inserted Mo film in a case where the Mo film thickness is 0.3 nm.

FIG. 4D is a characteristic diagram illustrating the magnetization curve (M-H loop) of the magnetization free layer, the dependency of the element resistance (RA) and the magnetoresistance ratio (MR ratio) on the thickness of the inserted Mo film, and the dependency of the holding capacity (Hc) of the magnetization free layer on the thickness of the inserted Mo film in a case where the Mo film thickness is 0.5 nm.

FIG. 4E is a characteristic diagram illustrating the magnetization curve (M-H loop) of the magnetization free layer, the dependency of the element resistance (RA) and the magnetoresistance ratio (MR ratio) on the thickness of the inserted Mo film, and the dependency of the holding capacity (Hc) of the magnetization free layer on the thickness of the inserted Mo film in a case where the Mo film thickness is 0.7 nm.

FIG. 4F is a characteristic diagram illustrating the magnetization curve (M-H loop) of the magnetization free layer, the dependency of the element resistance (RA) and the magnetoresistance ratio (MR ratio) on the thickness of the inserted Mo film, and the dependency of the holding capacity (Hc) of the magnetization free layer on the thickness of the inserted Mo film in a case where the Mo film thickness is 1.0 nm.

FIG. 5A is a characteristic diagram illustrating the dependency of the element resistance (RA) and the magnetoresistance ratio (MR ratio) on the thickness of the inserted Mo film.

FIG. 5B is a characteristic diagram illustrating the dependency of the holding capacity (Hc) of the magnetization free layer on the thickness of the inserted Mo film.

FIG. 6 is a characteristic diagram illustrating a result of examining behaviors of the element resistance (RA) and the magnetoresistance ratio (MR ratio) in a region where the film thickness is larger than 1.4 nm in the case of using a structure in which Mo with a film thickness of 0.5 nm has been inserted into a second-MgO film.

FIG. 7 is a characteristic diagram illustrating a relationship between the magnetoresistance ratio (MR ratio) and MgO(x+z)/Mo(y) in the thickness of the inserted Mo film.

FIG. 8 is a characteristic diagram illustrating the relationship in FIG. 7 as a relationship (@MR>100%) between the upper limit of MgO(x+z)/Mo(y) and the thickness of the inserted Mo film.

FIG. 9 is a characteristic diagram illustrating a relationship between a film thickness ratio (z/x) of the second-MgO films on and under the inserted Mo film and perpendicular magnetic anisotropy (Hk) of a magnetization free layer 55.

FIG. 10 is an equivalent circuit diagram of a memory cell array unit of an MRAM according to a second embodiment of the present technology.

FIG. 11 is a schematic cross-sectional view illustrating the cross-sectional structure of the memory cell of the MRAM according to the second embodiment of the present technology.

FIG. 12 is a schematic cross-sectional view in which a part of FIG. 11 has been enlarged.

FIG. 13 is a schematic diagram illustrating an overall configuration example of a camera (electronic equipment) to which the semiconductor device of the present technology has been applied.

### MODE FOR CARRYING OUT THE INVENTION

Hereinafter, embodiments of the present technology will be described with reference to the drawings. In the description of the drawings referred to in the following description, the same or similar parts are denoted by the same or similar reference numerals. However, it should be noted that the drawings are schematic, and the relationship between the thickness and the plane dimension, the ratio of the thickness of each layer, and the like are different from actual ones. Therefore, specific thicknesses and dimensions should be determined in consideration of the following description. Further, it is needless to say that parts having different dimensional relationships and ratios are included between the drawings. Moreover, the effects described in the present specification are merely examples, are not limited, and may have other effects.

Furthermore, the definitions of directions, such as upper and lower, in the following description are merely definitions for convenience of description and do not limit the technical idea of the present technology. For example, it is a matter of course that when an object is rotated by 90° and observed, the upper and lower sides are converted to the left and right and read, and when the object is rotated by 180° and observed, the upper and lower sides are inverted and read.

### First Embodiment

In the first embodiment, an example in which the present technology has been applied to a magnetoresistive effect element will be described.

### Configuration of Magnetoresistive Effect Element

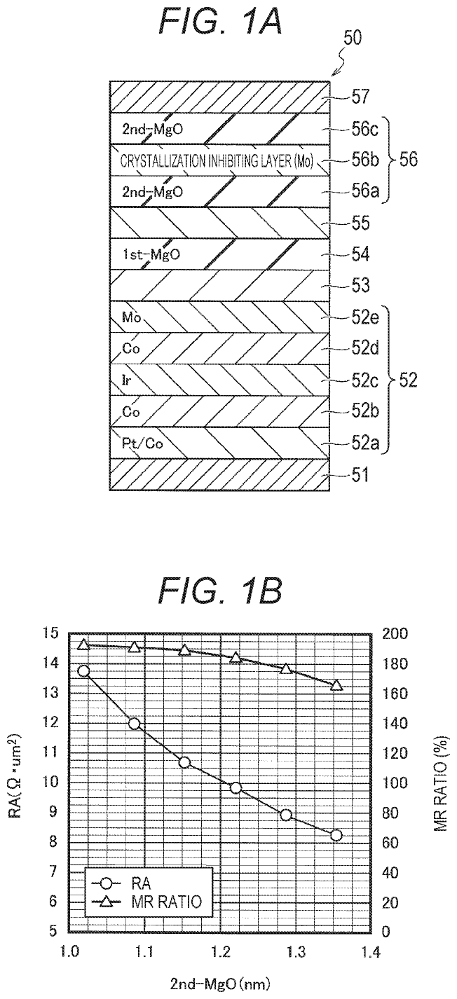

First, a configuration of a magnetoresistive effect element will be described with reference to FIG. 1.

As illustrated in FIG. 1, a magnetoresistive effect element 50 according to the first embodiment of the present technology includes: a magnetization fixed layer (reference layer) 53; a first oxide insulating layer (first nonmagnetic layer) 54 provided on one surface side of the magnetization fixed layer 53; a magnetization free layer (recording layer) 55 provided on the opposite side of the first oxide insulating layer 54 from the magnetization fixed layer 53 and having perpendicular magnetic anisotropy; a second oxide insulating layer (second nonmagnetic layer) 56 provided on the opposite side of the magnetization free layer 55 from the first oxide insulating layer 54; and a metal cap layer 57 provided on the opposite side of the second oxide insulating layer 56 from the magnetization free layer 55. The magnetization fixed layer 53, the first oxide insulating layer 54, the magnetization free layer 55, and the second oxide insulating layer 56 constitute a magnetic tunnel junction. The thickness of the second oxide insulating layer 56 is larger than the thickness of the first oxide insulating layer 54.

In addition, as illustrated in FIG. 1, the magnetoresistive effect element 50 according to the first embodiment of the present technology includes a lower electrode 51 provided on the opposite side of the magnetization fixed layer 53 from the first oxide insulating layer 54, and a multilayer metal layer 52 provided between the lower electrode 51 and the magnetization fixed layer 53.

The lower electrode 51 includes, for example, a Ta (tantalum) film. The multilayer metal layer 52 includes, for example, a laminated film 52a in which a platinum (Pt) film and a cobalt (Co) film are sequentially laminated from the lower electrode 51 side, and a cobalt (Co) film 52b, an iridium (Ir) film 52c, a cobalt (Co) film 52d, and a molybdenum (Mo) film 52e sequentially laminated on the opposite side of the laminated film 52a from the lower electrode 51.

The magnetization fixed layer 53 and the magnetization free layer 55 each include, for example, a CoFeB film. The first oxide insulating layer 54 includes, for example, a MgO film.

The second oxide insulating layer 56 includes a lower oxide insulating layer 56a, a crystallization inhibiting layer 56b, and an upper oxide insulating layer 56c sequentially laminated in this order on the opposite side of the magnetization free layer 55 from the first oxide insulating layer 54. That is, the second oxide insulating layer 56 has a multilayer structure with the crystallization inhibiting layer 56b inserted between the lower oxide insulating layer 56a and the upper oxide insulating layer 56c. The second oxide insulating layer 56, that is, the lower oxide insulating layer 56a and the upper oxide insulating layer 56c, includes, for example, a MgO film. The crystallization inhibiting layer 56b includes any film of a Ta (tantalum) film, an Ir film, a Cr film, a Mo film, a CoFeB30 film, and a Mg (magnesium) film, and includes, for example, a Mo film in the first embodiment. Then, the thickness of the upper oxide insulating layer 56c is larger than the thickness of the lower oxide insulating layer 56a. The metal cap layer 57 includes a multilayer film in which a Ta film, a Ru film, and a MgO film are sequentially laminated in this order from the second oxide insulating layer 56 side.

### Effects of First Embodiment

Next, a main effect of the first embodiment will be described in comparison with a conventional magnetoresistive effect element.

FIG. 1B is a characteristic diagram illustrating the dependency of element resistance (RA) and a magnetoresistance ratio (MR ratio) on the thickness of the MgO film in the lower and upper oxide insulating layers 56a, 56c of the second oxide insulating layer 56 in the magnetoresistive effect element 50 according to the first embodiment.

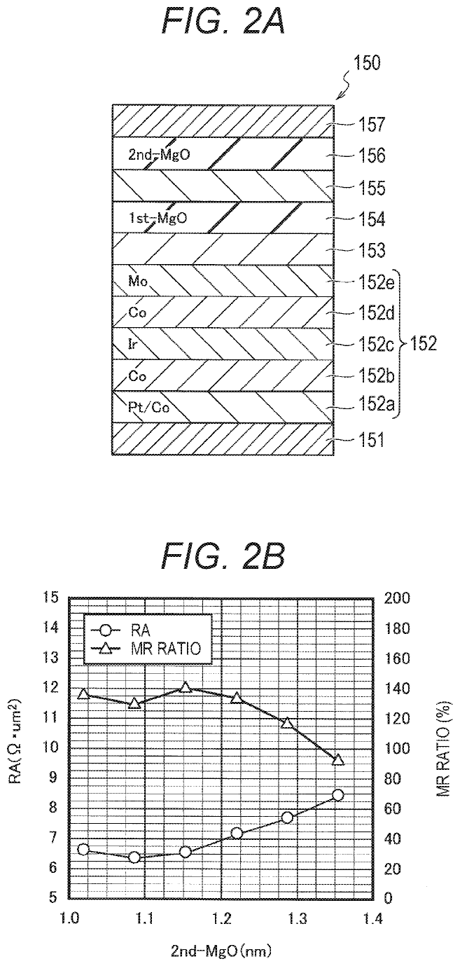

On the other hand, FIG. 2A is a schematic cross-sectional view illustrating a configuration example of a conventional magnetoresistive effect element. Then, FIG. 2B is a characteristic diagram illustrating the dependency of the element resistance (RA) and the magnetoresistance ratio (MR ratio) on the thickness of a second oxide insulating layer 156 in a conventional magnetoresistive effect element 150 in FIG. 2A.

As illustrated in FIG. 2A, the conventional magnetoresistive effect element 150 includes a lower electrode 151, and a multilayer metal layer 152, a magnetization fixed layer (reference layer) 153, a first oxide insulating layer 154, a magnetization free layer (recording layer) 155, a second oxide insulating layer 156, and a metal cap layer 157, which are sequentially laminated in this order on the lower electrode 151. Then, the conventional magnetoresistive effect element 150 includes similar materials to the magnetoresistive effect element 50 of the present technology, except for the second oxide insulating layer 156. That is, the lower electrode 151 includes a Ta film. The multilayer metal layer 152 includes a laminated film 152a in which a Pt film and a Co film are sequentially laminated from the lower electrode 51 side, and a Co film 152b, an Ir film 152c, a Co film 152d, and a Mo film 152e, which are sequentially laminated on the opposite side of the laminated film 152a from the lower electrode 151. The magnetization fixed layer 153 and the magnetization free layer 155 each include a CoFeB film. The first oxide insulating layer 154 and the second oxide insulating layer 156 each include, for example, a MgO film. The metal cap layer 157 includes a multilayer film in which a Ta film, a Ru film, and a MgO film are sequentially laminated in this order from the multilayer nonmagnetic layer 56 side.

The dependency of the element resistance (RA) and the magnetoresistance ratio (MR ratio) on the thickness of the MgO film in the second oxide insulating layer 56 in the magnetoresistive effect element 50 of the present technology illustrated in FIG. 1B, and the dependency of the element resistance (RA) and the magnetoresistance ratio (MR ratio) on the thickness of the MgO film in the second oxide insulating layer 156 in the conventional magnetoresistive effect element 150 illustrated in FIG. 2B were measured by performing heat treatment in a wafer process under the same conditions.

It was found that in the conventional magnetoresistive effect element 150, as is clear from FIG. 2B, when the thickness of the second oxide insulating layer (second-MgO film) 156 is set to be larger than 1.2 nm in order to withstand a wafer process at a relatively high temperature for a relatively long time, the element resistance (RA) of the magnetoresistive effect element 150 increases rapidly. As an estimation of the mechanism of this behavior, it was considered that the crystallization of the MgO film steeply proceeds in a region where the thickness of the second oxide insulating layer (second-MgO film) 156 is larger than 1.2 nm, and hence the element resistance (RA) also increases rapidly. Therefore, it was considered that when it is possible to prevent the rapid crystallization process of the second-MgO film in the second oxide insulating layer 156, it is also possible to prevent the increase in the element resistance (RA) with respect to the increase in the thickness of the second-Mg film.

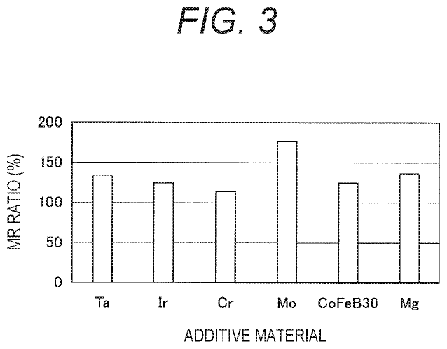

As a means for reducing and inhibiting the crystallization, the idea of inserting a metal material with a different crystal structure into the second-MgO film was developed. Here, FIG. 3 illustrates a part of results of intensive studies and evaluations on the insertion of metal materials such as a body-centered cubic structure (Mo, Cr, W) and a face-centered cubic structure (Ir) into MgO (cubic NaCl structure). FIG. 3 is a characteristic diagram illustrating a relationship between the material of the crystallization inhibiting layer 56b and the magnetoresistance ratio (MR ratio).

Here, Ta, Ir, Cr, Mo, CoFeB30, and Mg were selected as materials (additive materials) to be inserted into the second-MgO film and were inserted with a thickness of 0.5 nm, and the perpendicular magnetic anisotropy of the magnetization free layer 55 was examined. As a result, it was confirmed that all the insertion materials satisfy the magnetoresistance ratio (MR ratio)>100%.

In the following description, the case of selecting Mo as the material to be inserted into the second-MgO film will be described.

### Regulation of Thickness of Inserted Mo Film

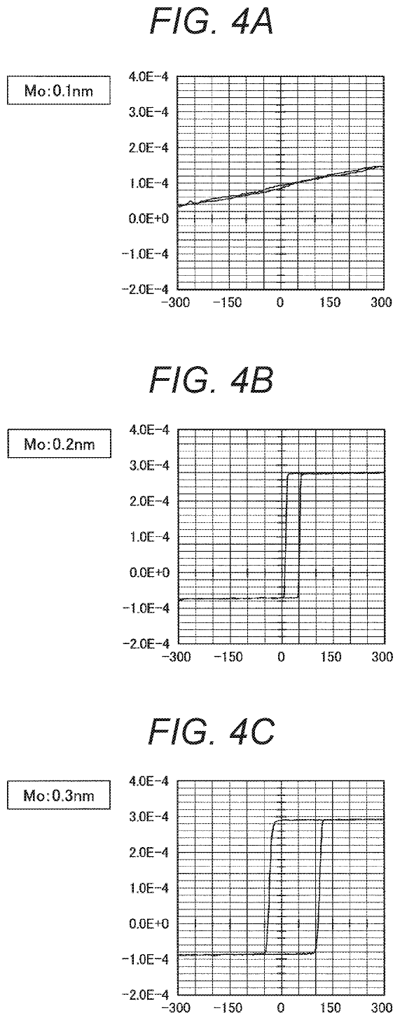

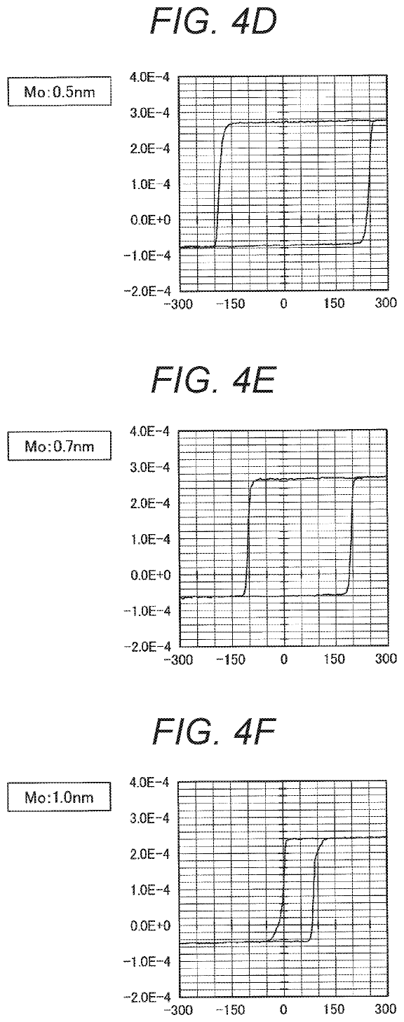

FIGS. 4A to 4F are characteristic diagrams illustrating the magnetization curve (M-H loop) of the magnetization free layer 55, the dependency of the element resistance (RA) and the magnetoresistance ratio (MR ratio) on the thickness of an inserted Mo film, and the dependency of the holding capacity (Hc) of the magnetization free layer 55 on the thickness of the inserted Mo film in a case where the thickness of the Mo film inserted as the crystallization inhibiting layer 56b between the lower oxide insulating layer 56a and the upper oxide insulating layer 56c of the second oxide insulating layer 56 (second-MgO film) is changed in the range of 0.1 nm to 1 nm in the magnetoresistive effect element 50 illustrated in FIG. 1 of the first embodiment.

As illustrated in FIGS. 4 to 4F, when the thickness of the inserted Mo film is changed in the range of 0.1 nm to 1 nm, the holding capacity (Hc) increases with the increase in the thickness of the inserted Mo film and turns to decrease with a peak at 0.5 nm.

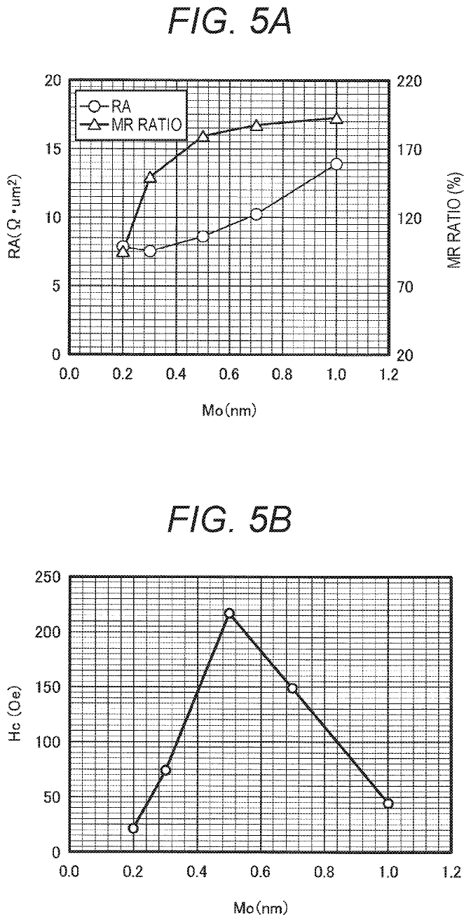

FIG. 5A is a characteristic diagram illustrating the dependency of the element resistance (RA) and the magnetoresistance ratio (MR ratio) on the thickness of the inserted Mo film, and FIG. 5B is a diagram illustrating the dependency of the holding capacity (Hc) of the magnetization free layer on the thickness of the inserted Mo film.

As illustrated in FIG. 5A, the element resistance (RA) gradually increases with the increase in the thickness of the inserted Mo film, and the magnetoresistance ratio (MR ratio) rapidly increases in the range of 0.2 nm to 0.3 nm and then gradually increases with the increase in the Mo film thickness. When the thickness of the inserted Mo film is defined in the range of the magnetoresistance ratio (MR ratio)>100% and the holding capacity (Hc) of the magnetization free layer 55>50 (Oe), the range of the thickness of the inserted Mo film is desirably in the range of 0.3 nm to 0.9 nm.

As described above, in the magnetoresistive effect element 50 of the present technology, the wafer is exposed to a relatively high-temperature process, so that it is desirable to set the thickness of the second-MgO film in a range larger than 1.4 nm.

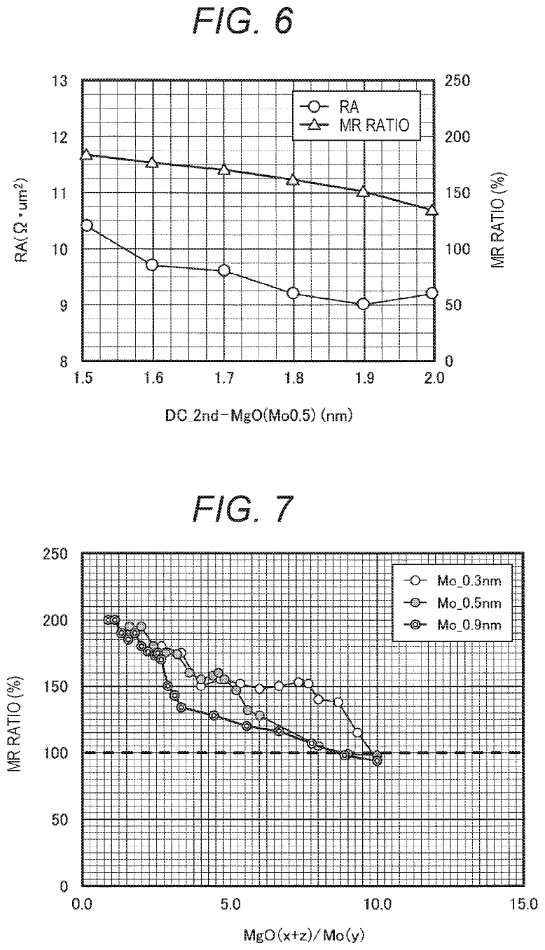

Next, in the magnetoresistive effect element 50 of the present technology, FIG. 6 illustrates a result of examining the behaviors of the element resistance (RA) and the magnetoresistance ratio (MR ratio) in a region where the film thickness is larger than 1.4 nm in the case of using a structure in which Mo with a film thickness of 0.5 nm has been inserted into the second-MgO film.

As illustrated in FIG. 6, in a case where the thickness of the second-MgO film of each of the lower oxide insulating layer 56a and the upper oxide insulating layer 56c is changed in the range of 1.5 nm to 2 nm, the element resistance (RA) tends to gradually decrease with an increase in the thickness of the second-MgO film, and when the thickness exceeds 1.9 nm, the element resistance (RA) tends to increase conversely. In addition, the magnetoresistance ratio (MR ratio) gradually decreases with the increase in the thickness of the second-MgO film. As can be seen from FIG. 6, in the case of using the structure in which Mo with a film thickness of 0.5 nm has been inserted into the second-MgO film, the magnetoresistance ratio (MR ratio)>130% is shown even in a region where the thickness of the second-MgO film is considerably as thick as 2 nm, and it is understood that it is possible to provide the magnetoresistive effect element 50 having a relatively high MR ratio while holding the perpendicular magnetic anisotropy of the magnetization free layer 55 even when the wafer is exposed to a relatively high-temperature process.

### Relationship Between MR and Film Thickness ratio of Mo Film Inserted into Second-MgO Film

FIG. 7 is a characteristic diagram illustrating a relationship between the magnetoresistance ratio (MR ratio) and MgO(x+z)/Mo(y) in each thickness of the inserted Mo film in a case where a relationship between the second-MgO film and the thickness of the Mo film inserted thereinto is represented by taking the thickness of the lower oxide insulating layer (second-MgO) 56a as X nm, the thickness of the crystallization inhibiting layer 56b as Y nm, and the thickness of the upper second oxide insulating layer (second-MgO) 56c as Z nm.

From FIG. 7, the film thickness ratio at which the magnetoresistance ratio (MR ratio)>100% can be ensured varies depending on the thickness of the inserted Mo film.

The film thickness ratio in a case where the Mo film thickness is 0.3 nm is [MgO(x+z)/Mo(y)]≤9.3, the film thickness ratio in a case where the Mo film thickness is 0.5 nm is [MgO(x+z)/Mo(y)]≤8.0, and the film thickness ratio in a case where the Mo film thickness is 0.9 nm is [MgO(x+z)/Mo(y)]≤7.8.

A desired thickness of the Mo film to be inserted with respect to the thickness of the second-MgO film is set so as to satisfy this relationship.

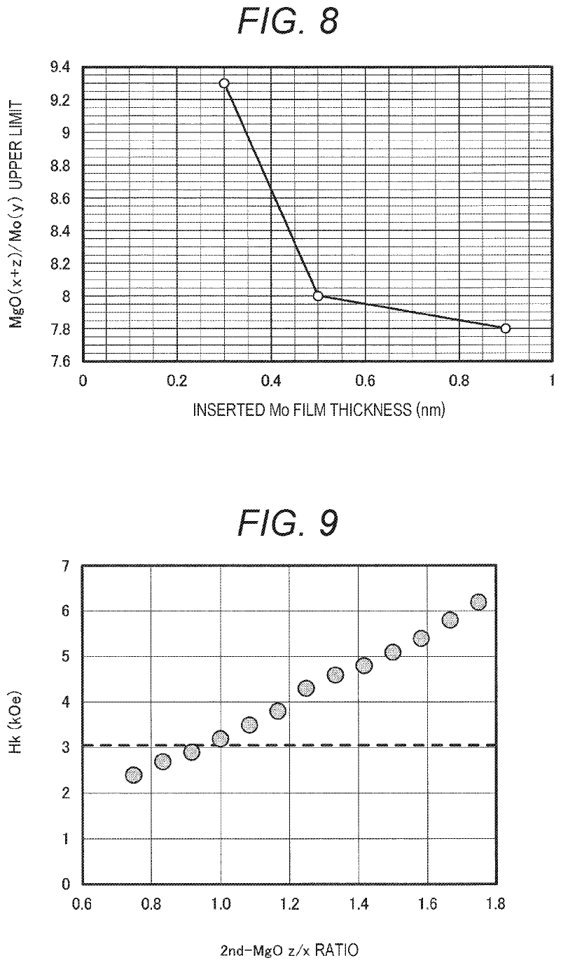

FIG. 8 is a characteristic diagram illustrating the relationship in FIG. 7 as a relationship (@MR>100%) between the upper limit of MgO(x+z)/Mo(y) and the thickness of the inserted Mo film.

From FIG. 8, the upper limit of the [MgO(x+z)/Mo(y)] film thickness ratio with respect to the desired thickness of the inserted Mo film can be confirmed.

Note that as described above, each of the Mo, CoFeB30, Ir, Cr, and Mg films is effective as the material of the crystallization inhibiting layer 56b to be inserted into the second-MgO film in the single layer. However, as a structure Z, which is a structure with a plurality of laminated layers, for inserting the crystallization inhibiting material, when the second-MgO is represented by MgO/Z/MgO, the structure Z is a laminated structure formed in a combination of Mo, CoFeB, Cr, W, and Ir, such as:

Mo/Cr/Mo,

Mo/W/Mo,

Mo/Ir/Mo,

CoFeB/Cr/CoFeB,

CoFeB/W/CoFeB, or

CoFeB/Ir/CoFeB,

the structure having been inserted into the second-MgO film as the crystallization inhibiting layer, and it has been confirmed that the structure has a similar effect to that described above.

Further, it has been confirmed that even in a structure where an oxide layer of TaO, TiO, SiO, AlO, or the like is inserted as an oxide layer except for MgO in addition to the metal insertion layer described above, the crystallization inhibiting material inserted into the second-MgO film has a similar effect.

Moreover, the magnetization free layer (second ferromagnetic layer) 55 is not limited to the CoFeB layer, and a ferromagnetic layer having a laminated structure of CoFeB and a plurality of materials selected from Mo, W, Ir, CoFe, Co, and Fe can also obtain a similar effect.

Furthermore, although the MgO films are used as the first and second oxide insulating layers 54, 56, it has been confirmed that a similar effect can be obtained even in the case of using a MgO film post-oxidized with oxygen, Ar and oxygen, or Ar, oxygen, and a reactive gas such as nitrogen after the formation of the Mg film, in addition to a MgO film including an oxide MgO target using Ar alone or Ar and a reactive gas except for Ar and a MgO film generated by a reactive sputtering method using a metal Mg target.

### Relationship between Film Thickness Ratio (z/x) of Second-MgO Film on and under Inserted Mo Film and Perpendicular Magnetic Anisotropy (Hk)

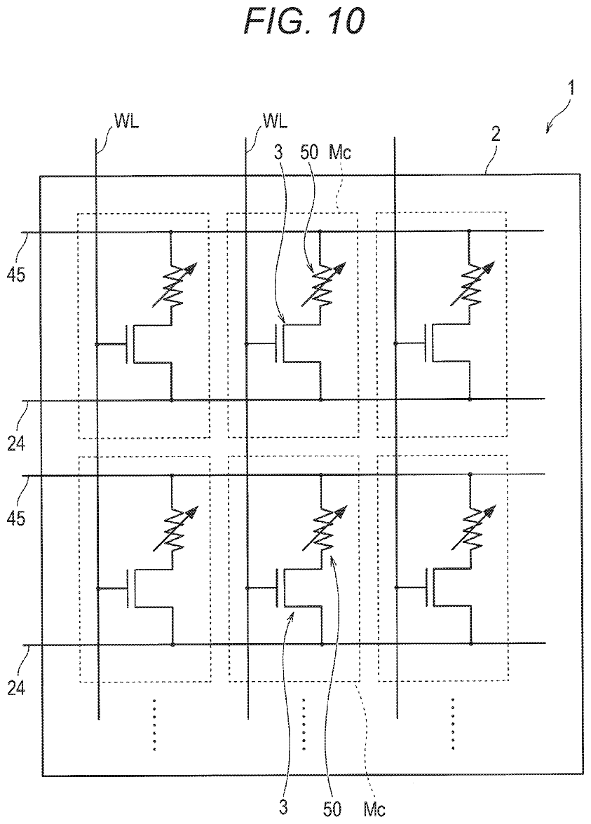

FIG. 9 is a characteristic diagram illustrating a relationship between the film thickness ratio (z/x) of the second-MgO films on and under the inserted Mo film (upper oxide insulating layer 5c and lower oxide insulating layer 56a) and the perpendicular magnetic anisotropy (Hk) of the magnetization free layer 55.

From the viewpoint of perpendicular magnetic anisotropy (Hk)>3 (kOe), the film thickness ratio (z/x) of the second-MgO film is desirably in a range of 1 or more. Hence there is desired a laminated structure of the second-MgO films, the structure satisfying the relationship of “the thickness (z) of the second-MgO films laminated on the upper side of the inserted Mo film”>“the thickness (x) of the second-MgO film”.

As described above, according to the first embodiment of the present technology, it is possible to provide the magnetoresistive effect element 50 that reduces the element resistance (RA) and has a relatively high magnetoresistance ratio (MR ratio).

### Second Embodiment

In the second embodiment, an example in which the present technology is applied to an MRAM as a semiconductor device will be described.

### Configuration of MRAM

As illustrated in FIG. 10, an MRAM 1 according to the second embodiment of the present technology includes a memory cell array unit 2 in which a plurality of memory cells Mc is arranged in a matrix. In the memory cell array unit 2, a plurality of pairs of a source line 24 and a data line 45 extending in the X direction are arranged in the Y direction at a predetermined arrangement pitch. Further, in the memory cell array unit 2, a plurality of word lines WL extending in the Y direction is arranged in the X direction at a predetermined arrangement pitch. The memory cell Mc is disposed at an intersection of the word line WL and the pair of the source line 24 and the data line 45. The memory cell Mc includes the magnetoresistive effect element 50 as a storage element and a cell selecting transistor 3 connected in series to the magnetoresistive effect element 50. The cell selecting transistor 3 includes, for example, a metal-insulator-semiconductor feild-effect-transistor (MISFET). Although not illustrated in detail, the memory cell array unit 2 is surrounded by a peripheral circuit unit in which peripheral circuits such as a word driver circuit, an X decoder circuit, and a Y decoder circuit are arranged.

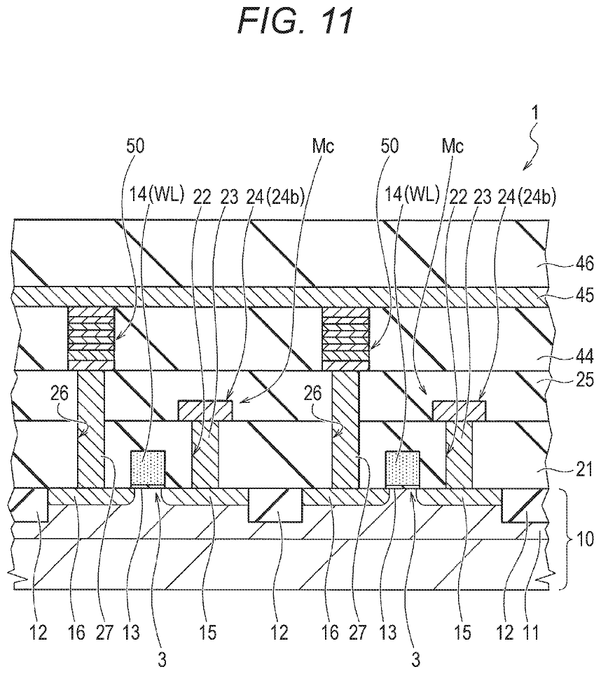

As illustrated in FIG. 11, the MRAM 1 mainly includes a semiconductor substrate 10. The semiconductor substrate 10 includes, for example, a p-type semiconductor substrate including single crystal silicon.

A well region 11 including a p-type semiconductor region is provided on the main surface of the semiconductor substrate 10. Further, an element isolation region 12 that defines an element formation region is provided on the main surface of the semiconductor substrate 10. The element isolation region 12 is formed by, but not limited to, a known shallow trench isolation (STI) technology, for example. The element isolation region 12 formed by the STI technology is formed, for example, by forming a shallow groove (e.g., a groove having a depth of about 300 [nm]) on the main surface of the semiconductor substrate 10, then forming an insulating film including, for example, a silicon oxide film on the entire surface of the main surface of the semiconductor substrate 10 including the inside of the shallow groove by chemical vapor deposition (CVD), and thereafter planarizing the insulating film by chemical mechanical polishing (CMP) so that the insulating film remains selectively inside the shallow groove. In addition, as another method of forming the element isolation region 12, the formation can be performed by the local oxidation of silicon (LOCOS) using a thermal oxidation method.

As illustrated in FIG. 11, the cell selecting transistor 3 of the memory cell Mc is provided in the element formation region on the main surface of the semiconductor substrate 10. The cell selecting transistor 3 includes a gate insulating film 13 provided on the main surface of the semiconductor substrate 10, a gate electrode 14 provided on the gate insulating film 13, and a pair of a first main electrode region 15 and a second main electrode region 16 provided on the surface layer portion (upper portion) of the well region 11 and functioning as a source region and a drain region. The gate insulating film 13 includes, for example, a silicon oxide film formed by oxidizing the main surface of the semiconductor substrate 10. The gate electrode 14 includes, for example, a polycrystalline silicon film into which impurities for reducing the resistance value has been introduced. The gate electrode 14 is formed as a pair with the word line WL and is configured by a part of the word line WL. The pair of the first main electrode region 15 and the second main electrode region 16 is provided on the surface layer portion of the well region 11 while being separated from each other in the gate length direction of the gate electrode 14, and is formed by self-alignment with respect to the gate electrode 14. A channel formation region is provided between the pair of the first main electrode region 15 and the second main electrode region 16. In the channel formation region, a channel is formed to electrically connect the pair of the first main electrode region 15 and the second main electrode region 16 by a voltage applied to the gate electrode. The pair of the first main electrode region 15 and the second main electrode region 16 includes an n-type semiconductor region.

As illustrated in FIG. 11, an interlayer insulating film 21 including, for example, a silicon oxide film is provided on the main surface of the semiconductor substrate 10. The interlayer insulating film 21 is provided with a connection hole 22 that reaches the surface of the first main electrode region 15 being the one of the pair in the cell selecting transistor 3 from the surface of the interlayer insulating film 21. Then, a conductive plug 23 is embedded in the connection hole 22.

A source line 24 is provided on the interlayer insulating film 21. Although not illustrated in detail, the source line 24 includes a trunk extending in the Y direction and a branch 24b protruding from the trunk onto the conductive plug 23 and electrically connected to the conductive plug 23. In FIG. 11, the branch 24b of the source line 24 is illustrated.

As illustrated in FIG. 11, an interlayer insulating film 25 including, for example, a silicon oxide film is provided on the interlayer insulating film 21 so as to cover the source line 24. The interlayer insulating film 25 and the interlayer insulating film 21 are provided with a connection hole 26 that reaches the surface of the second main electrode region 16 being the other of the pair in the cell selecting transistor 3 from the surface of the interlayer insulating film 25 through the interlayer insulating film 21. Then, a conductive plug 27 is embedded inside the connection hole 26.

As illustrated in FIG. 11, an interlayer insulating film 44 including, for example, a silicon oxide film is provided on the interlayer insulating film 25. The magnetoresistive effect element 50 of the memory cell Mc is embedded in the interlayer insulating film 44 at a position facing the conductive plug 27.

On the interlayer insulating film 44, a data line 45 is provided so as to cross over the magnetoresistive effect element 50. Then, on the interlayer insulating film 44, an interlayer insulating film 46 including, for example, a silicon oxide film is provided so as to cover the data line 45.

Note that, although other wires and other interlayer insulating films are provided on the interlayer insulating film 46, the illustration of the wires and the other interlayer insulating films on the upper layer of the interlayer insulating film 46 is omitted in FIG. 11.

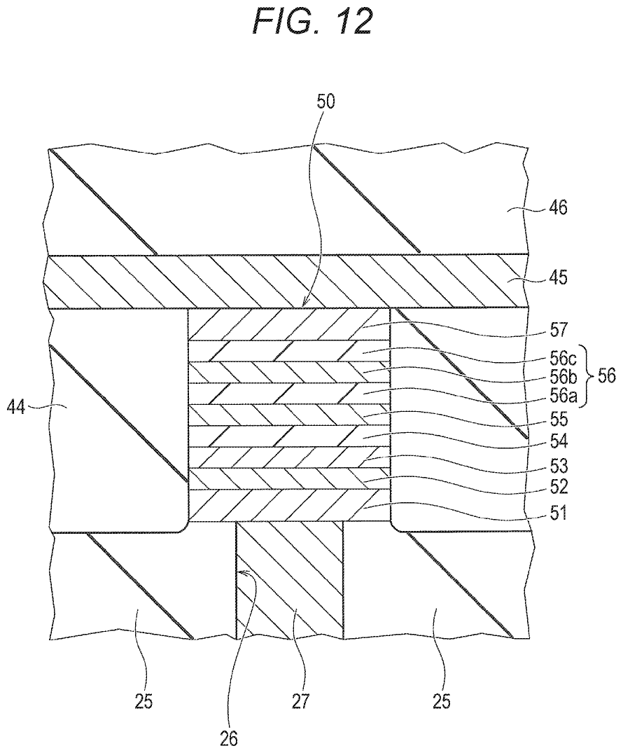

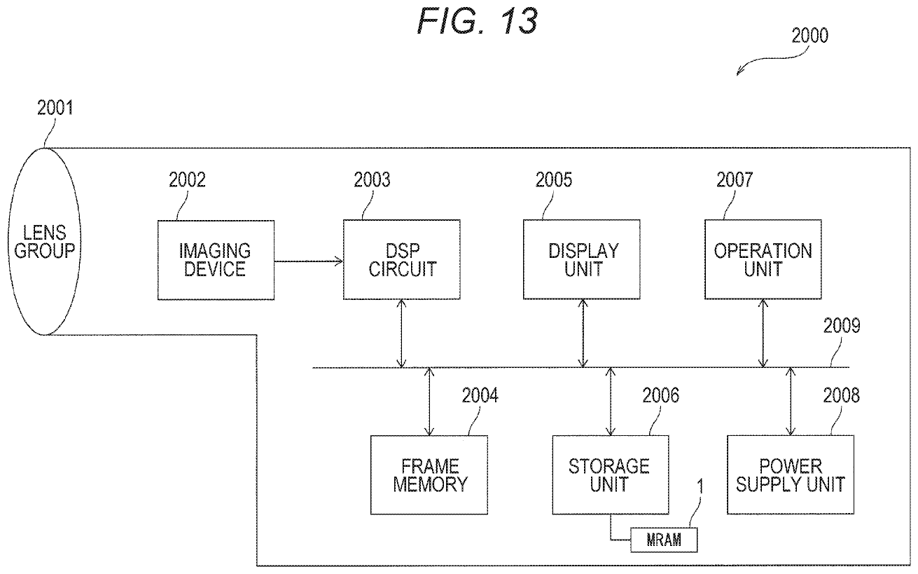

As illustrated in FIG. 12, the magnetoresistive effect element 50 includes a lower electrode 51 provided on the interlayer insulating film 25 so as to face the conductive plug 27, and a multilayer metal layer 52, a magnetization fixed layer (reference layer) 53, a first oxide insulating layer (first nonmagnetic layer) 54, a magnetization free layer (storage layer) 55, a second oxide insulating layer (second nonmagnetic layer) 56, and a metal cap layer 57, which are sequentially provided in this order on the lower electrode 51. The second oxide insulating layer 56 includes a lower oxide insulating layer 56a, a crystallization inhibiting layer 56b, and an upper oxide insulating layer 56c sequentially laminated in this order on the magnetic free layer 55. The lower electrode 51 is electrically and mechanically connected to the conductive plug 27. The metal cap layer 57 is electrically and mechanically connected to the data line 45.

### Writing and Reading of Memory Cell

The magnetization fixed layer 53 has a constant magnetization direction and serves as a reference of recording information (magnetization direction) of the magnetization free layer 55. With the magnetization fixed layer 53 being the reference of information, the magnetization direction should not be changed by writing or reading, but the magnetization fixed layer 53 does not necessarily need to be fixed in a specific direction, but at least the magnetization should be less mobile than in the magnetization free film.

The magnetization direction of the magnetization free layer 55 changes with respect to a voltage applied between the lower electrode 51 and the metal cap layer 57, and information is recorded in the magnetoresistive effect element 50 in accordance with the magnetization direction.

In the magnetoresistive effect element 50, a state in which the magnetization alignment of the two magnetic layers (the magnetization fixed layer 53 and the magnetization free layer 55) constituting the magnetic tunnel junction are parallel or antiparallel is set to “1” or “0”, respectively.

First, at the time of writing, the magnetization of the magnetization free layer 55 is reversed by a combined magnetic field generated by the currents flowing through the data line and the word line. At this time, the magnetization of the magnetization fixed layer 53 and the magnetization free layer 55 can be controlled to be parallel or antiparallel to each other by changing the direction of the current of the word line WL, thereby enabling the rewriting and erasing of information.

At the time of reading, the TMR effect is used. That is, the cell selecting transistor 3 is turned on, and a voltage drop generated by the current flowing through the magnetoresistive effect element 50 is measured. It is determined, from the magnitude of the voltage drop, whether the magnetization alignment of the magnetization fixed layer 53 and the magnetization free layer 55 is parallel (e.g., “1”) or antiparallel (e.g., “0”).

According to the MRAM 1 of the second embodiment, the writing and reading of data can be expected to be performed stably and at high speed by using the magnetoresistive effect element 50 described above.

Note that in the magnetoresistive effect element 50, the lower electrode 51 side may be connected to the cell selecting transistor 3, and the metal cap layer 57 side may be electrically connected to the data line 45.

### Configuration Example of Electronic Equipment

FIG. 13 is a block diagram illustrating a configuration example of a camera 2000 as electronic equipment to which the present technology has been applied.

The camera 2000 includes an optical unit 2001 made up of a lens group and the like, an imaging device 2002, and a digital signal processor (DSP) circuit 2003 that is a camera signal processing circuit. Further, the camera 2000 also includes a frame memory 2004, a display unit 2005, a recording unit 2006, an operation unit 2007, and a power supply unit 2008. The DSP circuit 2003, the frame memory 2004, the display unit 2005, the recording unit 2006, the operation unit 2007, and the power supply unit 2008 are connected to one another via a bus line 2009.

The optical unit 2001 captures incident light (image light) from a subject and forms the light as an image on the imaging surface of the imaging device 2002. The imaging device 2002 converts the light amount of the incident light formed as an image on the imaging surface by the optical unit 2001 into an electrical signal in units of pixels and outputs the electrical signal as a pixel signal.

The display unit 2005 includes, for example, a panel type display device such as a liquid crystal panel or an organic electroluminescent (EL) panel and displays a moving image or a still image captured by the imaging device 2002. The recording unit 2006 records the moving image or the still image captured by the imaging device 2002 on a recording medium such as a hard disk or the MRAM 1 as a semiconductor memory.

The operation unit 2007 issues operation commands for various functions of the camera 2000 under operation by the user. The power supply unit 2008 appropriately supplies various powers serving as operation power sources of the DSP circuit 2003, the frame memory 2004, the display unit 2005, the recording unit 2006, and the operation unit 2007 to these supply targets.

As described above, by using the MRAM 1 and the like described above as the recording medium of the recording unit 2006, it is possible to expect the acquisition of a good image.

Note that the present technology may have the following configuration.

(1)

A magnetoresistive effect element including:

a magnetization fixed layer;

a first oxide insulating layer provided on one surface side of the magnetization fixed layer;

a magnetization free layer provided on an opposite side of the first oxide insulating layer from the magnetization fixed layer side and having perpendicular magnetic anisotropy;

a second oxide insulating layer provided on an opposite side of the magnetization free layer from the first oxide insulating layer side; and

a metal cap layer provided on an opposite side of the second oxide insulating layer from the magnetization free layer side,

in which a thickness of the second oxide insulating layer is larger than a thickness of the first oxide insulating layer.

(2)

The magnetoresistive effect element according to (1) above,

in which the second oxide insulating layer includes a MgO film as a main component, and

a metal layer or an oxide layer except for MgO is inserted in the MgO film.

(3)

The magnetoresistive effect element according to (2) above, in which the metal layer includes at least any of a Ta film, an Ir film, a Cr film, a Mo film, a CoFeB film, or a Mg film.

(4)

The magnetoresistive effect element according to (2) above, in which a thickness of the metal layer is in a range of 0.3 nm to 0.9 nm.

(5)

The magnetoresistive effect element according to (2) above, in which a film thickness ratio between the MgO film and the metal layer is appropriately selected in accordance with a thickness of the metal layer.

(6)

The magnetoresistive effect element according to (2) above, in which in the second oxide insulating layer, a thickness on an upper side of the metal layer is larger than a thickness on a lower side of the metal layer.

(7)

A semiconductor device including a memory cell in which a magnetoresistive effect element and a selecting transistor are connected in series,

in which the magnetoresistive effect element includes

a magnetization fixed layer,

a first oxide insulating layer provided on one surface side of the magnetization fixed layer,

a magnetization free layer provided on an opposite side of the first oxide insulating layer from the magnetization fixed layer side and having perpendicular magnetic anisotropy,

a second oxide insulating layer provided on an opposite side of the magnetization free layer from the first oxide insulating layer side, and

a metal cap layer provided on an opposite side of the second oxide insulating layer from the magnetization free layer side, and

a thickness of the second oxide insulating layer is larger than a thickness of the first oxide insulating layer.

(8)

The semiconductor device according to (7) above, in which the second oxide insulating layer includes a MgO film as a main component, and a metal layer or an oxide layer other than MgO is inserted in the MgO film.

(9)

The semiconductor device according to (8) above, in which the metal layer includes at least any of a Ta film, an Ir film, a Cr film, a Mo film, a CoFeB film, or a Mg film.

(10)

The semiconductor device according to (8) above, in which an insertion thickness of the metal layer is in a range of 0.3 nm to 0.9 nm.

(11)

The semiconductor device according to (8) above, in which a film thickness ratio between the MgO film and the metal layer is appropriately selected in accordance with a thickness of the metal layer.

(12)

The semiconductor device according to (8) above, in which in the second oxide insulating layer, a thickness on an upper side of the metal layer is larger than a thickness on a lower side of the metal layer.

(13)

Electronic equipment including a semiconductor device that includes a magnetoresistive effect element,

in which the magnetoresistive effect element includes

a magnetization fixed layer,

a first oxide insulating layer provided on one surface side of the magnetization fixed layer,

a magnetization free layer provided on an opposite side of the first oxide insulating layer from the magnetization fixed layer side and having perpendicular magnetic anisotropy,

a second oxide insulating layer provided on an opposite side of the magnetization free layer from the first oxide insulating layer side, and

a metal cap layer provided on an opposite side of the second oxide insulating layer from the magnetization free layer side, and

a thickness of the second oxide insulating layer is larger than a thickness of the first oxide insulating layer.

The scope of the present technology is not limited to the illustrated and described exemplary embodiments but also includes all embodiments that provide equivalent effects to those for which the present technology is intended. Furthermore, the scope of the present technology is not limited to the combinations of the features of the invention defined by the claims but may be defined by any desired combination of specific features among all the features disclosed.

### REFERENCE SIGNS LIST

1 MRAM (semiconductor device)
2 Memory cell array unit
3 Cell selecting transistor
10 Semiconductor substrate
11 Well region
12 Element isolation region
13 Gate insulating film
14 Gate electrode
15 First main electrode region
16 Second main electrode region
21 Interlayer insulating film
22 Connection hole
23 Conductive plug
24 Source line
25 Interlayer insulating film
26 Connection hole
27 Conductive plug
44 Interlayer insulating film
45 Data line
46 Interlayer insulating film
50 Magnetoresistive effect element
51 Lower electrode
52 Multilayer metal layer
53 magnetization fixed layer
54 First oxide insulating layer
55 Magnetization free layer
56 Second oxide insulating layer
56a Lower oxide insulating layer
56b Crystallization inhibiting layer
56c Upper oxide insulating layer
57 Metal cap layer
Mc Memory cell
WL Word line

1. A magnetoresistive effect element comprising:
a magnetization fixed layer;
a first oxide insulating layer provided on one surface side of the magnetization fixed layer;
a magnetization free layer provided on an opposite side of the first oxide insulating layer from the magnetization fixed layer side and having perpendicular magnetic anisotropy;
a second oxide insulating layer provided on an opposite side of the magnetization free layer from the first oxide insulating layer side; and
a metal cap layer provided on an opposite side of the second oxide insulating layer from the magnetization free layer side,
wherein a thickness of the second oxide insulating layer is larger than a thickness of the first oxide insulating layer.

2. The magnetoresistive effect element according to claim 1,
wherein the second oxide insulating layer includes a MgO film as a main component, and
a metal layer or an oxide layer except for MgO is inserted in the MgO film.

3. The magnetoresistive effect element according to claim 2, wherein the metal layer includes at least any of a Ta film, an Ir film, a Cr film, a Mo film, a CoFeB film, or a Mg film.

4. The magnetoresistive effect element according to claim 2, wherein a thickness of the metal layer is in a range of 0.3 nm to 0.9 nm.

5. The magnetoresistive effect element according to claim 2, wherein a film thickness ratio between the MgO film and the metal layer is appropriately selected in accordance with a thickness of the metal layer.

6. The magnetoresistive effect element according to claim 2, wherein in the second oxide insulating layer, a thickness on an upper side of the metal layer is larger than a thickness on a lower side of the metal layer.

7. A semiconductor device comprising a memory cell in which a magnetoresistive effect element and a selecting transistor are connected in series,
wherein the magnetoresistive effect element includes
a magnetization fixed layer,
a first oxide insulating layer provided on one surface side of the magnetization fixed layer,
a magnetization free layer provided on an opposite side of the first oxide insulating layer from the magnetization fixed layer side and having perpendicular magnetic anisotropy,
a second oxide insulating layer provided on an opposite side of the magnetization free layer from the first oxide insulating layer side, and
a metal cap layer provided on an opposite side of the second oxide insulating layer from the magnetization free layer side, and
a thickness of the second oxide insulating layer is larger than a thickness of the first oxide insulating layer.

8. The semiconductor device according to claim 7,
wherein the second oxide insulating layer includes a MgO film as a main component, and
a metal layer or an oxide layer other than MgO is inserted in the MgO film.

9. The semiconductor device according to claim 8, wherein the metal layer includes at least any of a Ta film, an Ir film, a Cr film, a Mo film, a CoFeB film, or a Mg film.

10. The semiconductor device according to claim 8, wherein an insertion thickness of the metal layer is in a range of 0.3 nm to 0.9 nm.

11. The semiconductor device according to claim 8, wherein a film thickness ratio between the MgO film and the metal layer is appropriately selected in accordance with a thickness of the metal layer.

12. The semiconductor device according to claim 8, wherein in the second oxide insulating layer, a thickness on an upper side of the metal layer is larger than a thickness on a lower side of the metal layer.

13. Electronic equipment comprising a semiconductor device that includes a magnetoresistive effect element,
wherein the magnetoresistive effect element includes
a magnetization fixed layer,
a first oxide insulating layer provided on one surface side of the magnetization fixed layer,
a magnetization free layer provided on an opposite side of the first oxide insulating layer from the magnetization fixed layer side and having perpendicular magnetic anisotropy,
a second oxide insulating layer provided on an opposite side of the magnetization free layer from the first oxide insulating layer side, and
a metal cap layer provided on an opposite side of the second oxide insulating layer from the magnetization free layer side, and
a thickness of the second oxide insulating layer is larger than a thickness of the first oxide insulating layer.
